(19) United States
(12) Patent Application Publication
(10) Pub. No.: US 2026/0243052 A1
(43) Pub. Date: Aug. 20, 2026

(54) CONTROL BOX AND ENGINEERING MACHINERY

(71) Applicants: JIANGSU XCMG CONSTRUCTION MACHINERY RESEARCH INSTITUTE LTD., XUZHOU, JIANGSU (CN); XUZHOU XCMG PORT MACHINERY CO., LTD., XUZHOU, JIANGSU (CN)

(72) Inventors: He LIU, XUZHOU, JIANGSU (CN); Yilin LU, XUZHOU, JIANGSU (CN); Peng WANG, XUZHOU, JIANGSU (CN); Xiaofeng TANG, XUZHOU, JIANGSU (CN)

(73) Assignees: JIANGSU XCMG CONSTRUCTION MACHINERY RESEARCH INSTITUTE LTD., XUZHOU, JIANGSU (CN); XUZHOU XCMG PORT MACHINERY CO., LTD., XUZHOU, JIANGSU (CN)

(21) Appl. No.: 18/846,920

(22) PCT Filed: Mar. 20, 2023
(86) PCT No.: PCT/CN2023/082476

§ 371 Date: Sep. 13, 2024

(30) Foreign Application Priority Data
Feb. 22, 2023 (CN) 202310149344.8

(51) Int. Cl. E02F 9/20; H05K 5/02

(52) U.S. Cl. CPC E02F 9/2004; H05K 5/0217

(57) ABSTRACT

The present application provides a control box, which includes: a main box including a first box body and a handle disposed on the first box body; and an auxiliary box including a second box body and an electric apparatus disposed on the second box body, wherein the second box body is connected to one side of the first box body along a left-right direction or a front-rear direction of engineering machinery and is supported by the first box body. In this way, the space occupation of the control box is effectively reduced.

### CROSS-REFERENCE TO RELATED APPLICATIONS

The present application is based on and claims priority to Chinese application No. 202310149344.8, filed on Feb. 22, 2023, the entire contents of which are incorporated herein by reference.

### TECHNICAL FIELD

The present application relates to the technical field of engineering machinery, and in particular to a control box and an engineering machinery.

### BACKGROUND ART

A control box of engineering machinery is usually located in a cab for installation of handles, electrical elements, braking elements and the like. In general, the control box includes a main box mainly used for installation of the handles, and an auxiliary box mainly used for installation of the electrical elements.

In the related art, the auxiliary box and the main box of the control box are independent of each other, and are arranged separately from each other. In this case, the main box and the auxiliary box usually need to be provided with support structures respectively, therefore, the control box occupies a large space, which easily causes waste of the original space inside the cab.

### CONTENT OF THE INVENTION

A technical problem to be solved by the present application is to reduce the space occupation of the control box.

In order to solve the above technical problem, the present application provides a control box, including:
a main box including a first box body and a handle disposed on the first box body; and
an auxiliary box including a second box body and an electric apparatus, wherein the electric apparatus is disposed on the second box body, and the second box body is connected to one side of the first box body along a left-right direction or a front-rear direction of an engineering machinery and supported by the first box body.

In some embodiments, the second box body is hung on the first box body.

In some embodiments, the second box body is provided with an insertion plate, the first box body is provided with a slot, the insertion plate protrudes outward relative to the second box body and is inserted into the slot, and is connected with the first box body through a fastening apparatus to realize hanging connection between the second box body and the first box body.

In some embodiments, the insertion plate includes a first plate body and a second plate body. The fastening apparatus includes a first fastener and a second fastener, the first plate body is inserted into the slot, the second plate body extends downward from the first plate body and is located within the first box body, the first plate body is provided with a first hole, the second plate body is provided with a second hole, the first fastener passes through the first hole to connect the first plate body with the first box body, and the second fastener passes through the second hole to connect the second plate body with the first box body.

In some embodiments, a notch is provided on a sidewall of the second hole.

In some embodiments, the second hole is U-shaped.

In some embodiments, a support apparatus is provided in the first box body, a height of the support apparatus is adjustable so as to support the handles with different height dimensions; and/or, an exterior trim panel is provided on a top cover of the first box body, and the exterior trim panel is provided with a through hole to allow different handles to pass through.

In some embodiments, the support apparatus includes a first bracket disposed in the first box body, wherein the first bracket is provided with a connecting part which is configured to connect with second brackets of different heights, such that the height of the support apparatus is adjustable; and/or, the first bracket is movably arranged relative to the first box body, such that the height of the support apparatus is adjustable.

In some embodiments, the first bracket is disposed in the first box body in a vertical-slidable, telescopic or rotatable manner, such that the height of the support apparatus is adjustable.

In some embodiments, a top cover of the second box body includes a first cover body and a second cover body, the first cover body is connected to a front end of the second cover body, the electric apparatus is arranged on the first cover body, and the first cover body is gradually inclined upward along a direction from back to front.

In some embodiments, an upward inclination angle of the first cover body is greater than or equal to 3° and less than 90°.

In some embodiments, the control box includes a connecting piece, wherein the connecting piece connects the first box body and a seat of the engineering machinery, so that the main box is movable along with the seat in the front-rear direction of engineering machinery.

In some embodiments, the control box further includes a linkage mechanism, wherein the linkage mechanism connects the connecting piece with the first box body and enables the first box body to move back and forth and/or up and down relative to the seat.

In some embodiments, the control box includes at least two auxiliary boxes located on the same side or opposite sides of the main box.

In some embodiments, the at least two auxiliary boxes are located at the same side of the main box and are connected side by side along the left-right direction.

In addition, the present application also provides an engineering machinery including a control box in any embodiment of the present application.

In the present application, the auxiliary box is no longer independent of the main box, but is connected to one side of the main box along the left-right direction or the front-rear direction of the engineering machinery and is supported by the main box. In this way, it is unnecessary to equip the auxiliary box with a specific support structure, thereby effectively reducing space occupation.

Other features and advantages of the present application will become clear through the following detailed description of exemplary embodiments of the present application with reference to the attached drawings.

### BRIEF DESCRIPTION OF THE DRAWINGS

In order to explain the technical solution in the embodiment of the present application or that in the prior art more clearly, drawings required for describing the embodiment or the prior art will be briefly introduced below. Obviously, the attached drawings described below are only some examples of the present application. For those skilled in the art, other drawings can also be obtained according to these drawings without paying inventive effort.

FIG. 1 is a first perspective view of the control box in an embodiment of the present application.

FIG. 2 is a second perspective view of the control box in the embodiment of the present application.

FIG. 3 is a schematic exploded view of the combined structure of a main box, a connecting piece and a linkage mechanism in the embodiment of the present application.

FIG. 4 is a perspective view of the main box in the embodiment of the present application.

FIG. 5 is a perspective view of the auxiliary box in the embodiment of the present application.

FIG. 6 is a schematic exploded view of the auxiliary box in the embodiment of the present application.

FIG. 7 is a schematic view showing connection of the main box with the auxiliary box in the embodiment of the present application.

FIG. 8 is a partially enlarged sectional view of part I of FIG. 7.

FIG. 9 is a schematic view showing forces acting on the connection portion between the main box and the auxiliary box in the embodiment of the present application.

FIG. 10 is a schematic view showing the height dimension relationship between four kinds of handles to be mounted on the main box in the embodiment of the present application.

FIG. 11 is a schematic structural view in which the main box is equipped with a second handle in the embodiment of the present application.

FIG. 12 is a schematic structural view in which the main box is equipped with a first handle in the embodiment of the application.

FIG. 13 is a modified embodiment of the control box shown in FIG. 1.

FIG. 14 is a modified embodiment of the control box shown in FIG. 1.

### EMBODIMENTS

The technical solutions in the embodiments of the present application will be clearly and completely described with reference to the drawings in the embodiments of the present application. Obviously, the described embodiments are only part of the embodiments of the present application other than the whole embodiments. The following description for at least one exemplary embodiment is merely illustrative in actual and is in no way intended to limit the present application and its application or uses. All other embodiments that are obtained by those skilled in the art based on the embodiments of the present application without paying inventive effort fall within the protection scope of this application.

Techniques, methods and equipment known to those skilled in the art in the related art may not be discussed in detail, but they should be regarded as part of the description under appropriate circumstances.

In the depiction of the present application, it should be understood that the orientation or positional relationship indicated by words describing orientation such as “front, back, up, down, left, right”, “lateral, vertical, perpendicular, horizontal” and “top, bottom” is usually based on the attached drawings shown, just for the convenience of describing the present application and simplifying the depiction. Unless otherwise stated, these words describing orientation do not indicate or imply that the indicated devices or elements must have a specific orientation, or be constructed and operated in a specific orientation, so they shall not be construed as restricting the scope of protection of the present application. The words “inside, outside” refer to the inside and outside relative to the contour of a component itself.

In the depiction of the present application, it should be understood that the words “first”, “second” and the like are used to define parts only for the convenience of distinguishing the corresponding parts from each other. Unless otherwise stated, the above words have no special meaning, and thus shall not be construed as limiting the scope of protection of the present application.

In addition, the technical features involved in different embodiments of the present application described below can be combined with each other as long as they do not conflict with each other.

FIGS. 1-14 exemplarily show the structure of the control box of the present application.

Referring to FIGS. 1-14, in the present application, the control box 10 includes a main box 1 and an auxiliary box 2. The main box 1 includes a first box body 11, and a handle 12 disposed on the first box body 11. The auxiliary box 2 includes a second box body 21 and an electric apparatus 22 disposed on the second box body 21. The second box body 21 is connected to one side of the first box body 11 along a left-right direction or a front-rear direction of an engineering machinery and is supported by the first box body 11. It can be understood that the front-rear direction and the left-right direction of the engineering machinery are defined based on the normal driving state of the engineering machinery, where the direction in which the engineering machinery moves forwards is defined as “front”, the direction in which the engineering machinery moves backwards is defined as “rear”, and the “left” and “right” direction is respectively the left and right when people faces the front. The front-rear direction of the engineering machinery corresponds to a length direction of the main box 1. The left-right direction of the engineering machinery corresponds to a width direction of the main box 1.

In the above solution, the auxiliary box 2 is no longer independent of the main box 1, but is connected to one side of the main box 1 along the left-right direction or the front-rear direction of the engineering machinery and is supported by the main box 1. In this way, there is no need to provide a specific support structure for the auxiliary box 2, thus effectively reducing space occupation, improving a space utilization rate of the cab and saving costs.

Further, as the main box 1 is usually close to the main hand area of an operator, connection of the auxiliary box 2 to the main box 1 is also beneficial to reducing a distance between the auxiliary box 2 and the main hand area of the operator, which improves the convenience and comfort of operation, reduces the risk of operational fatigue, and improves work efficiency.

It can be seen that, by connecting the auxiliary box 2 to the main box 1 linked with the seat, the space occupation of the control box 10 is effectively reduced, and the control convenience of the control box 10 is improved.

In order to further improve the control convenience of the control box 10, referring to FIGS. 1-3, in some embodiments, the control box 10 further includes, in addition to the main box 1 and the auxiliary box 2, a connecting piece 31. The connecting piece 31 connects the first box body 11 with the seat of the engineering machinery, so that the main box 1 is movable in the front-rear direction of the engineering machinery together with the seat.

As the main box 1 is connected with the seat of the engineering machinery by the connecting piece 31, the main box 1 is linked with the seat. In this way, when drivers of different figures move the seat back and forth, the main box 1 can move back and forth together with the seat, so that the main box 1 is also adapted to the control requirements of drivers with different figures, thereby improving the control convenience and comfort, reducing the risk of operational fatigue, and improving work efficiency. Moreover, as the auxiliary box 2 is connected to the main box 1, the auxiliary box 2 can, together with the main box 1, move back and forth with the seat so as to adapt to the control requirements of drivers of different figures, which improves the control convenience and comfort, reduces the risk of operational fatigue, and improves work efficiency.

It can be seen that, by providing a connecting piece 31 to connect the main box 1, connected with the auxiliary box 2, to the seat, the control convenience and comfort of the control box 10 is further improved.

Further, referring to FIGS. 1-3, in some embodiments, the control box 10 includes not only the connecting piece 31, but also a linkage mechanism 32, which connects the connecting piece 31 with the first box body 11 and enables the first box body 11 to move back and forth and/or up and down relative to the seat. In this way, the main box 1 as well as the auxiliary box 2 connected with the main box 1 can not only move back and forth along with the seat, but also move back and forth and/or up and down relative to the seat, so that different control requirements are met more flexibly, and the control convenience and comfort are further improved.

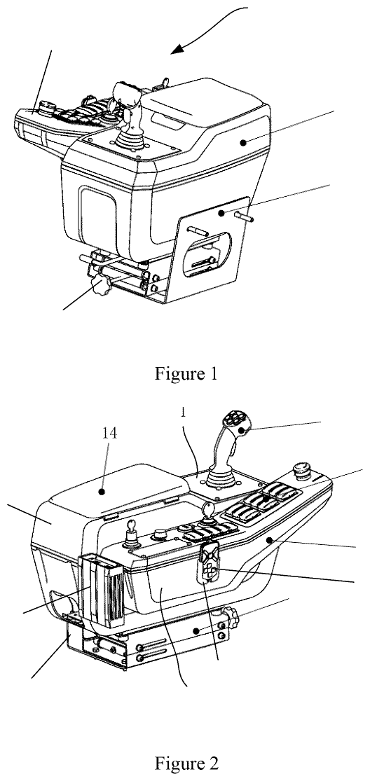

In the foregoing embodiments, the auxiliary box 2 may be connected with the main box 1 in various means. As an example, referring to FIGS. 2-9, in some embodiments, the second box body 21 is hung on the first box body 11. In this way, the assembly is convenient, the connection is reliable, and the detachable connection between the main box 1 and the auxiliary box 2 is convenient to realize, so that the main box 1 and the auxiliary box 2 can either be used in combination or be used separately, flexibly meeting different use requirements.

In order to achieve the hanging of the auxiliary box 2 to the main box 1, referring to FIGS. 2-9, in some embodiments, the second box body 21 is provided with an insertion plate 5, and the first box body 11 is provided with a slot 19. The insertion plate 5 protrudes outward relative to the second box body 21 and is inserted into the slot 19, and is connected with the first box body 11 through a fastening apparatus 8, thereby realizing the hanging of the second box body 21 to the first box body 11. In this case, the structure is simple, and the assembly is convenient.

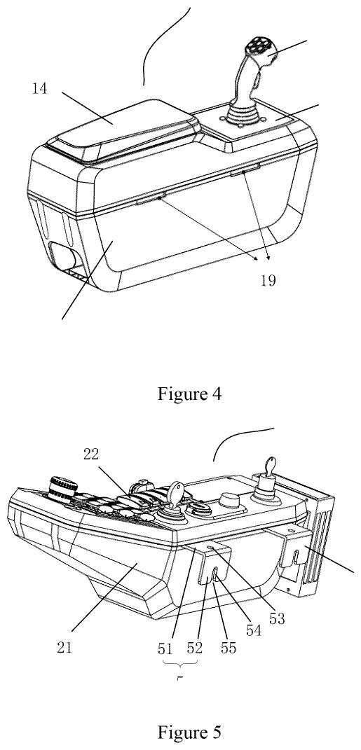

Specifically, referring to FIGS. 4-8, in some embodiments, the insertion plate 5 includes a first plate body 51 and a second plate body 52, and the fastening apparatus 8 includes a first fastener 81 and a second fastener 82. The first plate body 51 is inserted into the slot 19, and the second plate body 52 extends downward from the first plate body 51 and is located within the first box body 11. The first plate body 51 is provided with a first hole 53, and the second plate body 52 is provided with a second hole 54. The first fastener 81 passes through the first hole 53 to connect the first plate body 51 with the first box body 11, and the second fastener 82 passes through the second hole 54 to connect the second plate body 52 with the first box body 11.

Based on the above arrangement, the auxiliary box 2 is hung on the main box 1, the auxiliary box 2 is suspended in the air, and there is no need to set up a supporting structure underneath, therefore, the space occupation is effectively reduced, and the space is saved. Moreover, a tight and stable force lever is formed between the auxiliary box 2 and the main box 1, thereby realizing a stable arrangement of the auxiliary box 2 on one side of the main box 1.

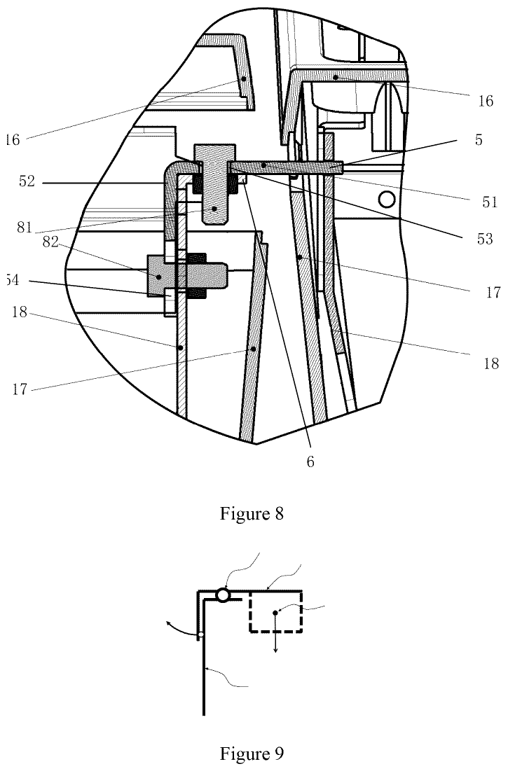

FIG. 9 is a force diagram of the above arrangement. Referring to FIG. 9, in the above solution, the auxiliary box 2 is suspended on one side of the main box 1. The auxiliary box 2, affected by its inherent weight, have a movement trend of rotating with the first fastener 81 as a fulcrum and a lower end of the insertion plate 5 as the movement limit. In this instance, on the basis of the first fastener 81 being provided for limiting position and fixation, the second fastener 82, connected to the second plate body 52 is further provided to suppress rotation, then a stable lever force form is formed, thereby the auxiliary box 2 from tipping over being prevented, and the arrangement stability of the auxiliary box 2 on one side of the main box 1 is improved.

Further, referring to FIG. 5, in some embodiments, a notch 55 is provided on a sidewall of the second hole 54. In this case, the second hole 54 is a non-closed hole, which not only restrains rotation by limiting the second fastener 82, but also facilitates the second fastener 82 to connect the second plate body 52 with the first box body 11, especially facilitates the second fastener 82 to connect the second plate body 52 with the first box body 11 within a relatively narrow first box body 11. This is beneficial to reducing the assembling difficulty and improving the assembling efficiency.

The second hole 54 may be in various shapes. For example, referring to FIG. 5, in some embodiments, the second hole 54 is U-shaped. In addition, the notch 55 may be located at any position of the sidewall of the second hole 54. For example, the notch 55 may be located at the lower end, upper end, left end and right end of the sidewall of the second hole 54.

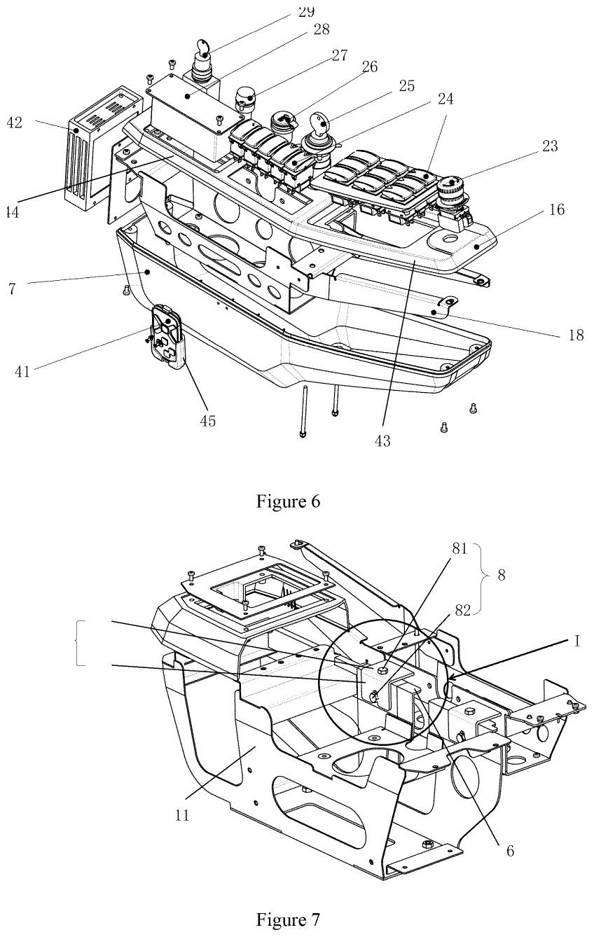

As a further modification to the aforementioned embodiments, referring to FIG. 6, in some embodiments, a top cover 16 of the second box body 21 includes a first cover body 43 and a second cover body 44. The first cover body 43 is connected to a front end of the second cover body 44, and the first cover body 43 is provided with an electric apparatus 22 and is gradually inclined upward along a direction from back to front. For example, in some embodiments, the angle at which the first cover body 43 is inclined upward is greater than or equal to 3° and less than 90°. In this way, it is convenient for the user to press and operate the electric apparatus 22 on the first cover body 43 by hand, and meets the requirement for visual observation, thus giving the user a comfortable experience and further improving the control comfort and convenience.

As mentioned above, the control box in the related art has the problems of inconvenient control and large occupation space. In fact, the control box in the related art also has the problem that it is difficult to be compatible with and meet the mounting requirements of handles of different specifications and thus has poor universality and expandability.

Specifically, various engineering machinery are more and more diversified in configuration and handles to be equipped in match are more and more diversified as well. The specifications of these handles are not the same, for example, electric control handles, thumb handles and hydraulic control handles have different control modes, height dimensions and working angles. However, in the related art, the control box is often designed for matching a certain type of handle, that is to say, the same main box can only be equipped with a handle of a certain specification, but cannot be equipped with handles of other specifications, and replacing with another type of handle often requires a completely new matching design, it is especially difficult to meet the mounting requirements of handles with different height dimensions. Thus, the control box has poor universality and later expansibility, which easily results in unnecessary waste and increased production costs.

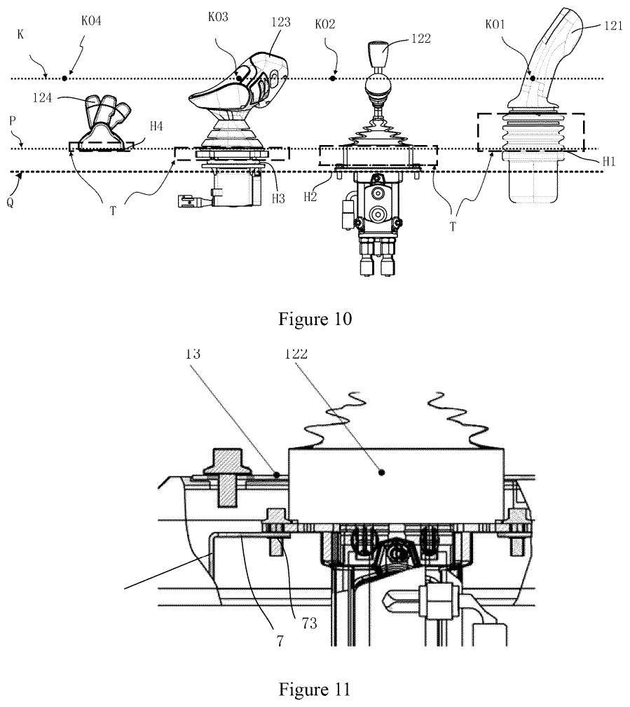

In order to solve the problem existing in the related art that the control box is difficult to be compatible with and meet the mounting requirements of handles with different specifications and thus has poor universality and expandability, referring to FIGS. 10-12, in some embodiments, the first box body 11 is provided therein with a support apparatus 7, the height of which is adjustable so as to support the handles 12 with different height dimensions.

As the support apparatus 7 in the main box 1 is adjustable in height to support the handles 12 with different height dimensions, the main box 1 can meet the mounting requirements of the handles 12 with different height dimensions. Accordingly, the same main box 1 can meet various configuration requirements. In this way, the universality and later expandability of the control box 10 is effectively improved, repeated design is reduced, and the design and manufacturing costs are reduced.

Further, by changing the height of the support apparatus 7, different handles 12 can all be put within a comfortable height range, then the control requirements of people with different figures is flexibly met and the control comfort is improved.

Various means may be employed to make the height of the support apparatus 7 adjustable.

As one of the means, referring to FIGS. 10-12, in some embodiments, the support apparatus 7 includes a first bracket 71, the first bracket 71 is disposed in the first box body 11, and is provided with a connecting part 73 for connection with second brackets 72 of different heights, such that the height of the support apparatus 7 is adjustable. In this instance, the height of the support apparatus 7 can be varied by connecting or not connecting a second bracket 72 and by changing the second bracket 72 of different heights, so as to meet the mounting requirements of the handles 12 with different height dimensions. For example, referring to FIGS. 9-12, in some embodiments, the first bracket 71 is arranged based on the height of the support apparatus 7 corresponding to any handle 12 of all the handles 12 to be mounted, and then the second brackets 72 with different height dimensions are switchably connected to the first bracket 71 (e.g. to an upper side and/or a lower side of the first bracket 71) to meet the mounting requirements of the other handles 12, that is, making the height of the first bracket 71 equal to the height of the support apparatus 7 corresponding to any handle 12 of all the handles 12 potentially to be mounted, and then replacing one second bracket 72 with another second brackets 72 of different height dimensions to match the other handles 12.

As another means of said various means, the support apparatus 7 includes a first bracket 71, and the first bracket 71 is movably arranged relative to the first box body 11, so as to make the height of the support apparatus 7 adjustable. In this case, the height of the support apparatus 7 can be varied by moving the first bracket 71, so as to meet the mounting requirements of the handles 12 with different height dimensions. The movement of the first bracket 71 may be at least one of the following: vertical sliding, extension and retraction, and rotation. For example, the first bracket 71 may be disposed in the first box body 11 in a vertically-slidable, telescopic or rotatable manner to make the height of the support apparatus 7 adjustable. It can be understood that, the first bracket 71 sliding vertically means that the first bracket 71 as an entirety slides vertically relative to the first box body 11, and the first bracket 71 being telescopic means that the first bracket 71 includes at least two sections which can slide up and down relatively.

The means of configuring the first bracket 71 to be movable and the means of replacing different second brackets 72 may be used alternatively or together. For example, in the case where the first bracket 71 is provided with the above-mentioned connecting part 73 for connection with the second brackets 72 of different heights, the first bracket 71 may be movable, and may also be immovable. When the first bracket 71 is movable, the mounting requirements of the handles 12 with different specifications can be met either by moving the first bracket 71, or by replacing different second brackets 72. In this way, the support apparatus 7 can adapt to the handles 12 of different specifications in more flexible means, and can meet the mounting requirements of the handles 12 within a wider height range, which is conducive to further improving the universality and later expandability of the control box 10.

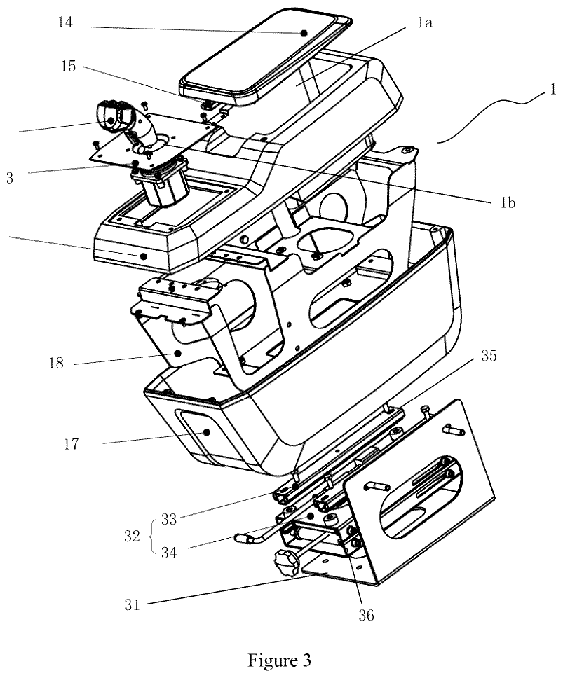

In addition, in order to solve the problem existing in the related art that the control box is difficult to be compatible with the mounting requirements of handles of different specifications and thus has poor universality and expandability, referring to FIG. 3, in some embodiments, an exterior trim panel 13, provided with a through hole 1b to allow different handles 12 to pass through, is provided on a top cover 16 of the first box body 11. In this way, the main box 1 can meet the mounting requirements of the handles with different widths, which is conducive to further improving the universality and later expansibility of the control box 10. It should be noted that, as an alternative, exterior trim panels 13 with through holes 1b of different sizes may be replaced to meet the mounting requirements of the handles with different widths.

In the foregoing embodiments, the auxiliary box 2 may be connected to one side of the main box 1 along the front-rear direction or one side of the main box 1 along the left-right direction. Compared with the instance that the auxiliary box 2 is connected to one side of the main box 1 along the front-rear direction, operation is more convenient when the auxiliary box 2 is connected to one side of the main box 1 along the left-right direction.

In addition, in the foregoing embodiments, the number of the auxiliary boxes 2 in the control box 10 may be one, two or more. Referring to FIGS. 13 and 14, when the control box 10 includes at least two auxiliary boxes 2, the at least two auxiliary boxes 2 may be located on the same side or opposite sides of the main box 1. Further, when the at least two auxiliary boxes 2 are located on the same side of the main box 1, the at least two auxiliary boxes 2 may be connected side by side along the left-right direction, so as to further facilitate operation.

Next, the present application will be further explained in combination with the embodiments shown in FIGS. 1-14.

A first embodiment shown in FIGS. 1-12 will be introduced first.

As shown in FIGS. 1-12, in this embodiment, the control box 10 includes a main box 1, a connecting piece 31, a linkage mechanism 32 and an auxiliary box 2.

The main box 1 is for installation of the handle 12. As shown in FIGS. 1-3 , in the embodiment, the main box 1 includes a first box body 11, a handle 12 and an elbow rest 14. The first box body 11 includes a top cover 16, a housing 17 and a framework 18. The top cover 16 of the first box body 11 is arranged on the top of the housing 17. The framework 18 of the first box body 11 is placed in the chamber enclosed by the top cover 16 and the housing 17. The handle 12 and the elbow rest 14 are both disposed on the top cover 16 of the first box body 11. As shown in FIGS. 2 and 3, the handle 12 is located on a front portion of the top cover 16 of the first box body 11, and the elbow rest 14 is located on a rear portion of the top cover 16 of the first box body 11.

Specifically, as shown in FIG. 3, a storage space la for storing articles is provided below the elbow rest 14 to meet the storage requirements of the user. Further, the elbow rest 14 is connected with the top cover 16 of the first box body 11 through a hinge 15, so that the elbow rest 14 can be opened and closed by rotation to expose or shield the storage space la below.

In order to realize installation of the handle 12, as shown in FIG. 3, in the embodiment, the top cover 16 of the first box body 11 is provided with an exterior trim panel 13 for shielding the mounting position of the handle, so that the handle 12 appears more beautiful and reliable after installation. The exterior trim panel 13 is provided with a through hole 1b, through which the handle 12 passes and extends into the interior of the first box body 11. A support apparatus 7 for supporting the handle 12 is provided in the first box body 11. The handle 12 extends into the first box body 11 through the through hole 1b and is supported by the support apparatus 7.

In the embodiment, in order to realize installation of the handles 12 with different specifications, the through hole 1b is configured to allow different handles 12 to pass through, so as to meet the mounting requirements of the handles with different widths. Further, as shown in FIGS. 9-11, the support apparatus 7 includes a first bracket 71 and a second bracket 72. The first bracket 71 is fixedly arranged in the first box body 11, and the second brackets 72 with different heights are detachably connected to the first bracket 71, so that the height of the support apparatus 7 can be varied by replacing different second brackets 72 to meet the mounting requirements of the handles with different heights. Specifically, a top surface of the first bracket 71 is provided with a connecting part 73, which is specifically a mounting hole, for connection with the second bracket 72 through fasteners such as bolts, so as to realize detachable connection between the first bracket 71 and the second bracket 72. Accordingly, the height of the support apparatus 7 can be varied by connecting or not connecting the second bracket 72 and by connecting second brackets 72 of different heights, thereby meeting the mounting requirements of the handles with different heights.

The through hole 1b has a size greater than or equal to the maximum width dimension of all the handles 12 potentially to be mounted, so that all the handles 12 potentially to be mounted can pass through the through hole 1b. In this case, an upper surface of the exterior trim panel 13 serves as an exterior finish of all the handles 12 potentially to be mounted, that is, all the handles 12 potentially to be mounted have a uniform exterior finish. The height position of the top surface of the first bracket 71 is equal to the height position of the top surface of the support apparatus 7 corresponding to the handle 12 with the lowest mounting position (that is, the required height of the top surface of the support apparatus 7 being the lowest) among all the handles 12 potentially to be mounted, so that the height of the support apparatus 7 can be varied by connecting or not connecting the second bracket 72 and connecting the second brackets 72 of different heights to the upper side of the first bracket 71 so as to meet the mounting requirements of handles with different heights.

For the purpose of better understanding, the arrangement of the support apparatus 7 in the embodiment will be described with reference to FIGS. 10-12 by taking the instance that four different specifications of handles 12 are to be mounted as an example.

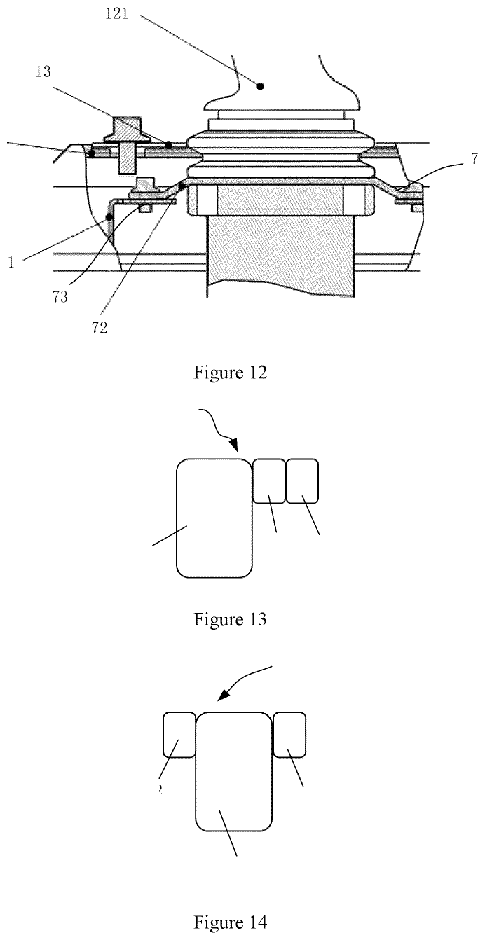

As shown in FIGS. 10-12, the handles 12 of four different specifications are a first handle 121, a second handle 122, a third handle 123 and a fourth handle 124 shown in sequence from right to left in FIG. 10. As shown in FIG. 10, the KO points (that is, the point corresponding to the center of the hand palm when the handle 12 is normally controlled, indicated as KO1, KO2, KO3 and KO4 respectively in FIG. 10) corresponding to the four handles 12 are at the same height position (as shown by the dotted line K in FIG. 10). Further, the four handles 12 have a unified exterior finish, that is, the exterior surfaces of the exterior trim panels 13 corresponding to the four handles are at the same height position (indicated by the straight line P in FIG. 10). In FIG. 10, the four dashed rectangular frames T respectively represent the possible height ranges of the exterior finishes corresponding to the four handles 12, and the four dashed rectangular frames overlap each other, which suggests that the four handles 12 can be configured to have a unified exterior finish. However, the height positions of the top surfaces of the support apparatuses 7 corresponding to the four handles 12 (that is, the mounting positions of the four handles 12) are different. The height positions of the top surfaces of the support apparatuses 7 corresponding to the first handle 121, the second handle 122, the third handle 123 and the fourth handle 124 are shown as H1, H2, H3 and H4 in FIG. 9 respectively. By comparison, it can be seen that the top surface of the support apparatus 7 corresponding to the second handle 122 is the lowest, and the top surfaces of the support apparatuses 7 corresponding to the first handle 121, the third handle 123 and the fourth handle 124 are all higher than the top surface of the support apparatus 7 corresponding to the second handle 122. In this instance, the mounting position of the second handle 122 is the lowest, and the height of the top surface of the support apparatus 7 corresponding to the second handle 122 is the lowest. Therefore, in the embodiment, the height position of the top surface of the support apparatus 7 corresponding to the second handle 122 is taken as the height position of the top surface of the first bracket 71 (which may be referred to as a universal handle mounting surface, indicated by the dotted line Q in FIG. 10), and the first bracket 71 is thereby arranged. Thus, as shown in FIG. 11, when the second handle 122 needs to be mounted, the second handle 122 is directly connected to the connecting part 73, and there is no need to mount the second bracket 72. When the first handle 121 needs to be mounted, as shown in FIG. 12, the second bracket 72, which can make up the height difference between the top surface of the support apparatus 7 corresponding to the first handle 121 and the top surface of the support apparatus 7 corresponding to the second handle 122, is connected to the connecting part 73 and disposed above the first bracket 71, so that the support apparatus 7 can meet the mounting requirements of the first handle 121. Similarly, when the third handle 123 or the fourth handle 124 needs to be mounted, second brackets 72 of different heights are disposed above the first bracket 71 to adapt to the third handle 123 and the fourth handle 124.

As can be seen, the main box 1 in the embodiment has good universality and later expansibility, and can flexibly meet the mounting requirements of handles 12 with different width and height dimensions. This is beneficial to realize lightweight design, effectively reduce mold costs, reduce the manufacturing and assembling difficulty, make the control box universal for various products, strongly support the lectotype and mating operation of other systems, and greatly reduce the related manufacturing and maintenance costs.

The connecting piece 31 and the linkage mechanism 32 are configured to connect the main box 1 with the seat, so as to realize the linkage and relative movement of the main box 1 and the seat. As shown in FIGS. 1-3, in the embodiment, the main box 1 is mounted on the linkage mechanism 32 and fixed to the seat through the connecting piece 31, thus forming a structure linked with the seat. Further, the linkage mechanism 32 includes a first adjustment mechanism 33 and a second adjustment mechanism 34. The first adjustment mechanism 33 includes a slide rail 35 extending in the front-rear direction, so that the first adjustment mechanism 33 enables the main box 1 to move back and forth relative to the seat. The second adjustment mechanism 34 includes a scissor-type lifting mechanism 36, so that the second adjustment mechanism 34 enables the main box 1 to move up and down relative to the seat. It can be seen that the linkage mechanism 32 in this embodiment enables the main box 1 to move back and forth and up and down relative to the seat. As the main box 1 can not only move back and forth along with the seat, but also move back and forth and up and down relative to the seat under the action of the connecting piece 31 and the linkage mechanism 32, the main box 1 can meet the control requirements of people with different figures and has good control comfort.

The auxiliary box 2 is for installation of the electric apparatus 22. As shown in FIGS. 5-6, in the embodiment, the auxiliary box 2 includes a second box body 21 and the electric apparatus 22. The second box body 21 includes a top cover 16, a housing 17 and a framework 18. The top cover 16 of the second box body 21 is arranged on the top of the housing 17. The framework 18 of the second box body 21 is disposed in the chamber enclosed by the top cover 16 and the housing 17. The electric apparatus 22 is arranged on the top cover 16 of the second box body 21 for operation by a user. As can be seen from FIG. 6, in the embodiment, the electric apparatus 22 includes electrical elements such as an emergency stop 23, rocker switches 24, a start switch 25, a charging port 26, an alarm 27, a radio 28, a forced start 29 and the like. All these electrical elements are arranged on the top cover 16 of the second box body 21.

Specifically, as shown in FIG. 6, in this embodiment, the top cover 16 of the second box body 21 includes a first cover body 43 and a second cover body 44, which are sequentially connected from front to back. The emergency stop 23 and part of the rocker switches 24 are arranged on the first cover body 43, and the other part of the rocker switches 24, the start switch 25, the charging port 26, the alarm 27, the radio 28 and the forced start 29 are all arranged on the second cover body 44. As can be seen from FIG. 6, the second cover body 44 is arranged approximately horizontally, and the first cover body 43 gradually inclines upward in a direction from back to front, and is in a tilted state. The angle between the first cover body 43 and the horizontal plane is 5-10°. In this case, the first cover body 43 tilts slightly, which is convenient for press and control by the hand of the driver, meets the requirement for direct visual observation, thereby bring better comfortable experience.

With further reference to FIG. 6, in the embodiment, the second box body 21 is further provided with a mounting part 45 and an intercom 42. The mounting part 45 is configured to install a megaphone 41, which is detachably connected to the mounting part 45, such that mating megaphones 41 can be replaced according to actual requirement. Specifically, as shown in FIG. 6, in the embodiment, the megaphone 41 is arranged on one side of the second box body 21 in the left-right direction, and the intercom 42 is arranged at the rear side of the second box body 21.

In the embodiment, the auxiliary box 2 is a separate modular body, on such basis, various configurations of the auxiliary boxes can be realized and modular design can be realized only by replacing the top covers 16 of the second box body 21 corresponding to the mounting space and mounting location of various electrical elements to assemble with the housing 17 in a small overall size.

Moreover, as shown in FIGS. 3-9, in the embodiment, the auxiliary box 2 is connected to one side of the main box 1 along the left-right direction in a suspended manner, and is mounted and fixed using a force lever structure, thereby achieving the suspended arrangement of the auxiliary box 2, which effectively saves the overall space. Further, the auxiliary box 2 can move, together with the main box 1, along with and relative to the seat, thereby improving the control convenience and comfort.

Specifically, in the embodiment, as shown in FIG. 4, two slots 19 are provided on one side of the first box body 11 of the main box 1 in the left-right direction, and the two slots 19 are arranged at intervals in the front-rear direction, moreover, correspondingly, as shown in FIG. 5, two insertion plates 5 are provided on one side of the second box body 21 of the auxiliary box 2 facing the main box 1. The two insertion plates 5 correspond to the two slots 19 respectively, and have identical structures, including a first plate body 51 and a second plate body 52 connected in an L-shape. The first plate body 51 extends horizontally, and the second plate body 52 extends vertically downward from the first plate body 51. The first plate body 51 and the second plate body 52 are provided with a first hole 53 and a second hole 54 respectively. The first hole 53 is a closed circular hole, and penetrates through the first plate body 51 along a thickness direction (i.e., vertical direction) of the first plate body 51. The second hole 54 is a U-shaped hole, which is located at the lower end of the second plate body 52, and penetrates through the second plate body 52 along the thickness direction (i.e. left-right direction) of the second plate body 52, with the U-shaped opening facing downward, that is, the lower end of the second hole 54 is provided with a notch 55.

With the cooperation of the two insertion plates 5 with the main box 1, the auxiliary box 2 is suspended on one side of the main box 1 along the left-right direction. As shown in FIGS. 7-8, in the embodiment, the first box body 11 of the main box 1 is provided therein with bent plates 6 corresponding to the two insertion plates 5 respectively. After being inserted through the two slots 19, the two insertion plates 5 correspond to the two bent plates 6 respectively, the first plate body 51 of each insertion plate 5 is located above a transverse portion of the corresponding bent plate 6, while the second plate body 52 of each insertion plate 5 is located on an inner side of a vertical portion of the corresponding bent plate 6, and the transverse portions and the vertical portions of the bent plates 6 are provided with corresponding connection holes corresponding to the first hole 53 and the second hole 54 respectively. In this way, the first fastener 81 is inserted into the first hole 53 and the corresponding connection hole in the transverse portion of the bent plate 6 along the vertical direction to lock, and the second fastener 82 is inserted into the second hole 54 and corresponding connection hole in the vertical portion of the bent plate 6 along the left-right direction to lock, then the insertion plates 5 and the first box body 11 are coupled and locked, forming a tight and stable stressed lever form, and realizing suspended connection of the auxiliary box 2 to on one side of the main box along the left-right direction. Specifically, in the embodiment, the insertion plate 5 is disposed on the framework 18 of the auxiliary box 2, the bent plate 6 is disposed on the framework 18 of the main box 1, and both the first fastener 81 and the second fastener 82 include bolts.

The adoption of the above-mentioned connection structure realizes suspended arrangement of the auxiliary box 2 on one side of the main box 1 along the left-right direction, which saves space and effectively restrain rotation of the suspended auxiliary box 2 to realize stable arrangement of the auxiliary box 2 in the left-right direction of the main box 1. What's more, this enables convenient and efficient assembly.

The control box 10 in this embodiment may be assembled generally by the steps of:
connecting the housing 17 and the intercom 42 of the auxiliary box 2 with the framework 18 by fasteners, and fixing the megaphone 41 to the housing 17 of the auxiliary box 2 by fasteners;
mounting the electrical elements such as the rocker switches 24, the emergency stop 23, the start switch 25, the charging port 26, the alarm 27, the radio 28, the forced start 29 and the like on the top cover 16 of the auxiliary box 2, assembling the assembled top cover 16 of the auxiliary box 2 with the housing 17 of the auxiliary box 2, and fastening with fasteners, so as to form the auxiliary box 2, in this process, replacing top covers 16 of the auxiliary box 2 with different configurations according to different configuration requirements and sizes of the electrical components, then different configurations of the auxiliary boxes 2are obtained.
connecting the housing 17 of the main box 1 with the framework 18 by fasteners;
placing the auxiliary box 2 on one side of the main box 1, inserting the insertion plates 5 of the auxiliary box 2 into the slots 19, inserting the first fasteners 81 into the first holes 53 and the connection holes on the transverse portions of the bent plates 6, and fastening with nuts, and in the same way, penetrating the second fasteners 82 through the second holes 54 and the connection holes on the vertical portions of the bent plates 6 to fix, so as to form a stable force lever structure, such that the framework 18 of the auxiliary box 2 is suspended on the framework 18 of the main box 1, and then connecting the top cover 16 of the main box 1 with the frameworks 18 of the main box 1 and the auxiliary box 2 by fasteners to realize suspended connection of the auxiliary box 2 to a side of the main box 1;
connecting the handle 12 and the elbow rest 14 with the assembled main box 1 through fasteners, fixing the main box 1 to the linkage mechanism 32, and connecting the main box 1 with the seat by means of the connecting piece 31.

It can be seen that the control box 10 in the embodiment has the advantages of simple structure, convenient assembly, saved space, convenient control and strong universality, and can meet the requirements of different configurations, which is beneficial to improve the layout compactness of the cab, realize the universality of cab molds for different products, improve the mold utilization rate, save the mold cost investment, reduce the difficulty of manufacturing and assembly, and realize the lightweight and intensive design of products.

Next, a second embodiment shown in FIG. 13 will be described. In order to simplify the description, only the differences between the second embodiment and the first embodiment are described here, and what is not described can be understood with reference to the first embodiment.

As shown in FIG. 13, the main difference between said second embodiment and the aforementioned first embodiment lies in that, two, other than one, auxiliary boxes 2 are provided. The two auxiliary boxes 2 are arranged on the same side of the main box 1 along the left-right direction and arranged side by side in the left-right direction. The first auxiliary box 2 is connected with the main box 1 in a suspended way, and the second auxiliary box 2 is suspended on a side of the first auxiliary box 2 away from the main box 1.

Next, a third embodiment shown in FIG. 14 will be introduced. In order to simplify the description, only the differences between the third embodiment and the first embodiment are described here, and what is not described can be understood with reference to the first embodiment.

As shown in FIG. 14, the main difference between the third embodiment and the aforementioned first embodiment is mainly that the number of the auxiliary boxes 2 is not one, but two, and the two auxiliary boxes 2 are arranged on the left and right sides of the main box 1 respectively. The two auxiliary boxes 2 are both connected to the main box 1 in a suspended manner.

Based on the control box 10 in the aforementioned embodiments, the present application also provides an engineering machinery including the control box in any embodiment of the present application. As an example, the engineering machinery is an engineering vehicle such as a loader.

The above is only an exemplary embodiment of this application, and it is not used to limit this application. Any modification, equivalent substitution, modification, etc. made within the spirit and principle of this application should be included in the protection scope of this application.

1. A control box of an engineering machinery, comprising:
a main box comprising a first box body and a handle disposed on the first box body; and
an auxiliary box comprising a second box body and an electric apparatus, wherein the electric apparatus is disposed on the second box body and the second box body is connected to one side of the first box body along a left-right direction or a front-rear direction of an engineering machinery and is supported by the first box body.

2. The control box according to claim 1, wherein the second box body is hung on the first box body.

3. The control box according to claim 2, wherein the second box body is provided with an insertion plate, the first box body is provided with a slot, the insertion plate protrudes outward relative to the second box body and is inserted into the slot, and is connected with the first box body through a fastening apparatus to realize hanging connection between the second box body and the first box body.

4. The control box according to claim 3, wherein the insertion plate comprises a first plate body and a second plate body, the fastening apparatus comprises a first fastener and a second fastener, the first plate body is inserted into the slot the second plate body, extends downward from the first plate body and is located in the first box body the first plate body is provided with a first hole, the second plate body is provided with a second hole the first fastener passes through the first hole to connect the first plate body with the first box body, and the second fastener passes through the second hole to connect the second plate body with the first box body.

5. The control box according to claim 4, wherein a notch is provided on a sidewall of the second hole.

6. The control box according to claim 5, wherein the second hole is U-shaped.

7. The control box according to claim 1, wherein a support apparatus is provided in the first box body a height of the support apparatus is adjustable so as to support the handles with different height dimensions;
and/or, an exterior trim panel is provided on a top cover of the first box body, and the exterior trim panel is provided with a through hole to allow different handles to pass through.

8. The control box according to claim 7, wherein the support apparatus comprises a first bracket disposed in the first box body, wherein the first bracket is provided with a connecting part which is configured to connect with second brackets of different heights, such that the height of the support apparatus is adjustable;
and/or, the first bracket is movably arranged relative to the first box body, such that the height of the support apparatus is adjustable.

9. The control box according to claim 8, wherein the first bracket is disposed in the first box body in a vertical-slidable, telescopic or rotatable manner, such that the height of the support apparatus is adjustable.

10. The control box according to claim 1, wherein a top cover of the second box body comprises a first cover body and a second cover body, the first cover body is connected to a front end of the second cover body, the electric apparatus is arranged on the first cover body and the first cover body is gradually inclined upward along a direction from back to front.

11. The control box according to claim 10, wherein an upward inclination angle of the first cover body is greater than or equal to 3° and less than 90°.

12. The control box according to claim 1, comprising a connecting piece, wherein the connecting piece connects the first box body and a seat of the engineering machinery, so that the main box is movable along with the seat in the front-rear direction of engineering machinery.

13. The control box according to claim 12, further comprising a linkage mechanism wherein the linkage mechanism connects the connecting piece with the first box body and enables the first box body to move back and forth and/or up and down relative to the seat.

14. The control box according to claim 1, comprising at least two auxiliary boxes located on the same side or opposite sides of the main box

15. The control box according to claim 14, wherein the at least two auxiliary boxes are located at the same side of the main box and are connected side by side along the left-right direction.

16. An engineering machinery, comprising the control box according to claim 1.
